(19) United States
(12) Patent Application Publication
(10) Pub. No.: US 2022/0003506 A1
(43) Pub. Date: Jan. 6, 2022

(54) VAPOR CHAMBER

(71) Applicant: Delta Electronics, Inc., Taoyuan City (TW)

(72) Inventors: Chao-Wen Lu, Taoyuan City (TW); Ting-Yuan Wu, Taoyuan City (TW)

(21) Appl. No.: 17/169,261

(22) Filed: Feb. 5, 2021

(30) Foreign Application Priority Data
Jul. 3, 2020 (CN) 202010631565.5

(51) Int. Cl. F28D 15/02; F28D 15/04; H01L 23/427

(52) U.S. Cl. CPC F28D 15/0233; F28D 15/046; F28F 2225/04; F28F 2240/00; H01L 23/427

(57) ABSTRACT

The present disclosure provides a vapor chamber. The vapor chamber comprises a first casing, a second casing and a working fluid. The first casing has a first recess and a plurality of pillars. A fluid channel is formed among the plurality of pillars. The second casing has a second recess and a microstructure. The microstructure has a plurality of liquid storing concaves. The first casing is assembled with the second casing, the first recess and the second recess are sealed to form an accommodating space, and the plurality of pillars are corresponding in position to the microstructure. The working fluid is accommodated in the accommodating space and absorbed among the plurality of pillars and the microstructure by the capillary force, and flows in the fluid channel and the plurality of liquid storing concaves.

### FIELD OF THE INVENTION

The present disclosure relates to a heat dissipation device, and more particularly to a vapor chamber.

### BACKGROUND OF THE INVENTION

With the development and improvement of the technology, the operating efficiency of the electronic device is improved gradually, and the power of the electronic components of the electronic device is also increased. Since the thermal energy generated by the electronic components during operation is increased, the heat dissipation of the electronic components becomes more important. At present, the vapor chamber is a common heat dissipation device to be assembled within the electronic device to achieve the heat dissipation of the electronic components.

A conventional vapor chamber comprises a housing, a mesh structure and a working fluid. The housing comprises a vacuum chamber. The mesh structure is disposed within the vacuum chamber of the housing for absorbing the working fluid in the accommodation space of the housing. The working fluid is transferred from a cold end to a hot end by the evaporation and the condensation cycle of the working fluid and the capillary force between the working fluid and the mesh structure to achieve the effect of temperature equalization and heat dissipation. Since the development of the electronic device tends to be thinner and thinner, the thickness of the vapor chamber is also required to be thinned. Accordingly, the mesh structure is required to be formed by thin and fine copper wires. However, the thin copper mesh of the mesh structure needs higher fabricating cost, and the capillary force between the working fluid and the thin copper mesh is reduced and the resistance of the working fluid is also increased. Therefore, the diffusion speed of the working fluid in the mesh structure becomes slower and poor heat dissipation efficiency of the vapor chamber is caused.

On the other hand, a vapor channel is formed within the mesh structure of the conventional vapor chamber and disposed along a direction parallel to the thickness of the vapor chamber. When the vapor chamber is required to be thinned, the mesh structure is also need to be thinned. Since the mesh structure is thinner, the vapor channel becomes too small to absorb the cooled working liquid. Consequently, poor heat dissipation efficiency of the vapor chamber is caused.

Therefore, there is a need of providing an improved vapor chamber to obviate the drawbacks of the prior art.

### SUMMARY OF THE INVENTION

It is an object of the present disclosure to provide a vapor chamber to achieve the advantages of slimness, reducing the resistance of the working fluid and increasing the storage of the working liquid, and achieve rapid transportation of thermal energy and enhance the heat dissipation efficiency.

It is an object of the present disclosure to provide a vapor chamber. The vapor chamber comprises a first casing, a second casing and a working fluid. The first casing has a first recess and a plurality of pillars. The first recess has a first bottom surface, and the plurality of pillars are disposed on the first bottom surface. A fluid channel is formed among the plurality of pillars. The second casing has a second recess and a microstructure. The second recess has a second bottom surface, and the microstructure is disposed on the second bottom surface. The microstructure has a plurality of liquid storing concaves. When the first casing is assembled with the second casing, the first recess and the second recess are sealed to form an accommodating space, and the plurality of pillars are disposed corresponding in position to the microstructure. The working fluid is accommodated in the accommodating space and absorbed among the plurality of pillars and the microstructure by the capillary force, and flows in the fluid channel and the plurality of liquid storing concaves.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating a vapor chamber according to a first embodiment of the present disclosure;

FIG. 2 is a schematic exploded view illustrating the vapor chamber according to the first embodiment of the present disclosure;

FIG. 3 is a schematic perspective view illustrating the first casing of the vapor chamber according to the first embodiment of the present disclosure;

FIG. 4 is a schematic cross-sectional view illustrating the vapor chamber of FIG. 1 and taken along the line A-A;

FIG. 5 is a schematic cross-sectional view illustrating the vapor chamber according to the first embodiment of the present disclosure, wherein the vapor chamber is in contact with a heat source;

FIG. 6 is a schematic perspective view illustrating a vapor chamber according to a second embodiment of the present disclosure;

FIG. 7 is a schematic exploded view illustrating the vapor chamber according to the second embodiment of the present disclosure;

FIG. 8 is a schematic cross-sectional view illustrating the vapor chamber according to the second embodiment of the present disclosure;

FIG. 9 is a schematic cross-sectional view illustrating a microstructure of the vapor chamber according to the second embodiment of the present disclosure;

FIG. 10 is a schematic partial-perspective view illustrating the microstructure of the vapor chamber according to the second embodiment of the present disclosure; and

FIG. 11 is a schematic cross-sectional view illustrating the vapor chamber according to the second embodiment of the present disclosure, wherein the vapor chamber is in contact with a heat source.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

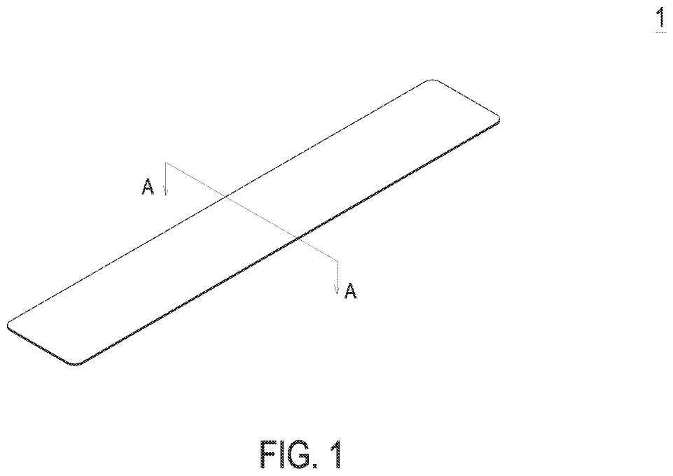

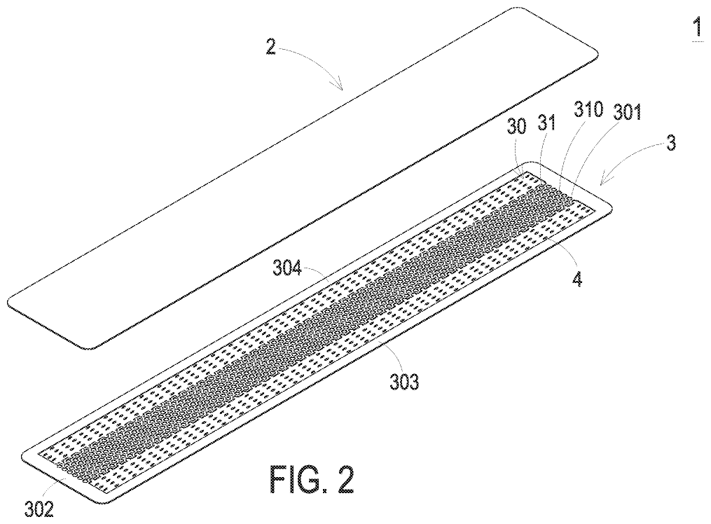

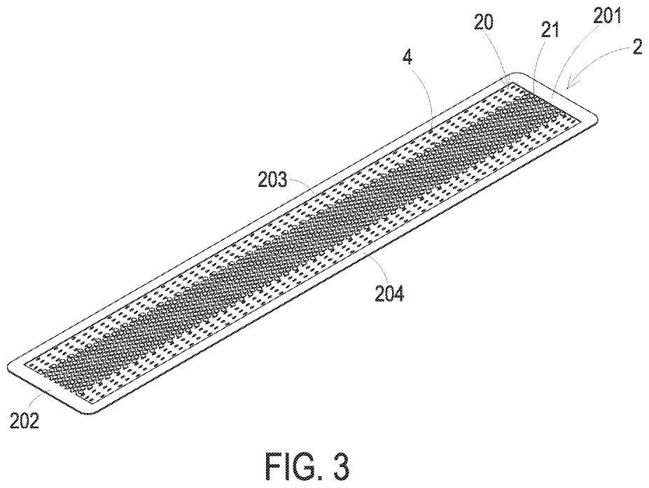

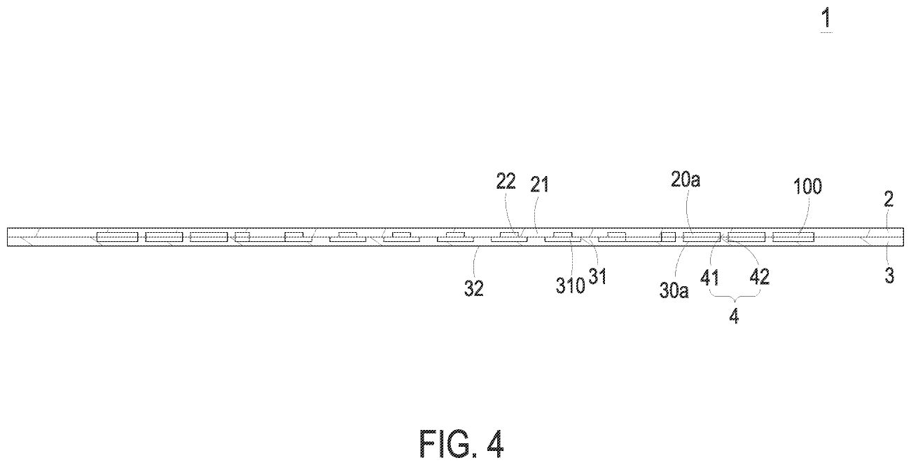

FIG. 1 is a schematic perspective view illustrating a vapor chamber according to a first embodiment of the present disclosure, FIG. 2 is a schematic exploded view illustrating the vapor chamber according to the first embodiment of the present disclosure, FIG. 3 is a schematic perspective view illustrating the first casing of the vapor chamber according to the first embodiment of the present disclosure, and FIG. 4 is a schematic cross-sectional view illustrating the vapor chamber of FIG. 1 and taken along the line A-A. In the first embodiment, the vapor chamber 1 comprises a first casing 2, a second casing 3 and a working fluid (not shown). The first casing 2 has a first recess 20 and a plurality of pillars 21. The first recess 20 has a first bottom surface 20a, the plurality of pillars 21 are disposed on the first bottom surface 20a, and a fluid channel 22 is formed among the plurality of pillars 21. The second casing 3 has a second recess 30 and a microstructure 31. The second recess 30 has a second bottom surface 30a, and the microstructure 31 is disposed on the second bottom surface 30a. The microstructure 31 is corresponding in position to the plurality of pillars 21 so as to form an aligned arrangement, that is, each of the pillars 21 is corresponding in position to the microstructure 31. The microstructure 31 has a plurality of liquid storing concaves 310. The plurality of liquid storing concaves 310 are blind holes which are not penetrated through the second casing 3 for accommodating the working liquid. When the first casing 2 and the second casing 3 are assembled, the first recess 20 and the second recess 30 are sealed to form an accommodating space 100, and the plurality of pillars 21 of the first casing 2 is in contact with and aligned to the microstructure 31 of the second casing 3. When the working liquid is accommodated within the accommodating space 100, due to the aligned arrangement of the pillars 21 and the microstructure 31, the working liquid is absorbed among the plurality of pillars 21 and the microstructure 31 by the capillary force, and flows in the fluid channel 22 and the plurality of liquid storing concaves 310. In this embodiment, since the plurality of pillars 21 of the first casing 2 is corresponding in position to the microstructure 31 of the second casing 3, the working fluid is absorbed by the capillary force among the plurality of pillars 21 and the microstructure 31, so that the mesh structure of the conventional vapor chamber is replaced by the plurality of pillars 21 and the microstructure 31 and a thinner thickness of the vapor chamber is achieved. Preferably but not exclusively, the thickness of the vapor chamber 1 is less than or equal to 0.6 millimeter (mm). More preferably, the thickness of the vapor chamber 1 is less than or equal to 0.3 millimeter (mm). In addition, since the plurality of pillars 21 are disposed corresponding in position to the microstructure 31, it is unnecessary to use a metal-made mesh structure of the conventional vapor chamber to absorb the working liquid therein. Therefore, the advantages of reducing the resistance of the working fluid, transporting thermal energy rapidly and enhancing the heat dissipation efficiency are achieved.

In this embodiment, the first casing 2 and the second casing 3 are made of a metal material, respectively, for example but not limited to a copper or a copper alloy. Each of the plurality of pillars 21 is a polygonal cylinder, for example but not limited to a hexagon cylinder. The plurality of pillars 21 are arranged in an interleaved array, and the fluid channels 22 are formed among the plurality of pillars 21 so that a honeycomb-shaped capillary structure is formed. In this embodiment, the plurality of liquid storing concaves 310 are concavely formed on the surface of the microstructure 31. The liquid storing concaves 310 are blind holes which are not penetrated through the second casing 3. Each of liquid storing concaves 310 is a polygonal concave, for example but not limited to a hexagon concave. The plurality of liquid storing concaves 310 are arranged in an interleaved array, so that a honeycomb-shaped liquid storing structure is formed. In an embodiment, each of the liquid storing concaves 310 is an independent concave, and any two of the liquid storing concaves 310 are not in fluid communication with each other. Since the working liquid is capable of being stored within the plurality of liquid storing concaves 310, the storage of the working liquid is increased, and the heat dissipation efficiency of the vapor chamber 1 is enhanced.

In this embodiment, the accommodating space 100 of the vapor chamber 1 is a vacuum chamber. The first recess 20 of the first casing 2 has a first sidewall 201, a second sidewall 202, a third sidewall 203 and a fourth sidewall 204. The first sidewall 201 is opposite to the second sidewall 202. The first sidewall 201 and the second sidewall 202 are respectively disposed adjacent to two short sides of the vapor chamber 1. The third sidewall 203 is opposite to the fourth sidewall 204. The third sidewall 203 and the fourth sidewall 204 are respectively disposed adjacent to two long sides of the vapor chamber 1. The honeycomb-shaped capillary structure formed by the plurality of pillars 21 and the fluid channel 22 is disposed by extending from a middle portion of the first sidewall 201 of the first recess 20 to a middle portion of the second sidewall 202. The two opposite sides of the honeycomb-shaped capillary structure are respectively close to and apart from the third sidewall 203 and the fourth sidewall 204 of the first recess 20. The second recess 30 of the second casing 3 has a first sidewall 301, a second sidewall 302, a third sidewall 303 and a fourth sidewall 304. The first sidewall 301 is opposite to the second sidewall 302. The first sidewall 301 and the second sidewall 302 are respectively disposed adjacent to two short sides of the vapor chamber 1. The third sidewall 303 is opposite to the fourth sidewall 304. The third sidewall 303 and the fourth sidewall 304 are respectively disposed adjacent to two long sides of the vapor chamber 1. The honeycomb-shaped liquid storing structure formed by the plurality of liquid storing concaves 310 and the microstructure 31 is disposed by extending from a middle portion of the first sidewall 301 of the second recess 30 to a middle portion of the second sidewall 302. The two opposite sides of the honeycomb-shaped liquid storing structure are respectively close to and apart from the third sidewall 303 and the fourth sidewall 304 of the second recess 30. In an embodiment, the honeycomb-shaped capillary structure of the first casing 2 is corresponding in position to the honeycomb-shaped liquid storing structure of the second casing 3.

In this embodiment, the first recess 20, the plurality of pillars 21 and the fluid channel 22 of the first casing 2 are formed by an etching process. The first recess 20, the plurality of pillars 21 and the fluid channel 22 are integrally formed with the first casing 2 in one piece. The second recess 30, the microstructure 31 and the plurality of liquid storing concaves 310 of the second casing 3 are formed by the etching process. The second recess 30, the microstructure 31 and the plurality of liquid storing concaves 310 are integrally formed with the second casing 3 in one piece. Since the foregoing structures are formed by the etching process, the thickness of the vapor chamber 1 can be thinned.

In an embodiment, when the first casing 2 is assembled with the second casing 3, each of the pillars 21 is misaligned with a corresponding one of the liquid storing concaves 310. That is, each of the pillars 21 is partially overlapped with the corresponding one of the liquid storing concaves 310. A free end of each of the pillars 21 does not completely close the opening of the corresponding one of the liquid storing concaves 310, and only a part of the free end of each of the pillars 21 covers the opening of the corresponding one of the liquid storing concaves 310. In other words, each of the liquid storing concaves 310 is in fluid communication with the fluid channel 22 formed by the plurality of pillars 21, so that the working liquid or the vaporized working liquid is allowed to flow among the plurality of liquid storing concaves 310 and the fluid channel 22.

In some embodiments, when the first casing 2 is assembled with the second casing 3, each of the pillars 21 is aligned with a corresponding one of the liquid storing concaves 310. That is, each of the pillars 21 is overlapped within the opening of the corresponding one of the liquid storing concaves 310, and the area of the opening of each of the liquid storing concaves 310 is greater than the surface area of a free end of the corresponding one of the pillars 21. Since the opening of the liquid storing concave 310 is greater than the surface area of the free end of the pillar 21, the pillar 21 doesn't completely close the opening of the liquid storing concave 310 while overlapped with the liquid storing concave 310. In other words, each of the liquid storing concaves 310 is in fluid communication with the fluid channel 22 formed by the plurality of pillars 21, so that the working liquid or the vaporized working liquid is allowed to flow among the plurality of liquid storing concaves 310 and the fluid channel 22.

In this embodiment, the vapor chamber 1 further comprises a plurality of supporting structures 4. The plurality of supporting structures 4 are disposed within the accommodating space 100 and disposed between the first bottom surface 20a of the first casing 2 and the second bottom surface 30a of the second casing 3. In an embodiment, each of the supporting structures 4 has a first supporting column 41 and a second supporting column 42. The first supporting column 41 is disposed on the first bottom surface 20a of the first casing 2, and the second supporting column 42 is disposed on the second bottom surface 30a of the second casing 3. The second supporting columns 42 are corresponding in position to the first supporting columns 41, respectively. When the first casing 2 and the second casing 3 of the vapor chamber 1 are assembled, the first supporting column 41 and the second supporting column 42 are aligned and in contact with each other. In an embodiment, the plurality of first supporting columns 41 are arranged on the first bottom surface 20a of the first recess 20 in an array. A part of the plurality of first supporting columns 41 is located among the first sidewall 201, the second sidewall 202, the third sidewall 203 and the honeycomb-shaped capillary structure of the first recess 20. The other part of the plurality of first supporting columns 41 is located among the first sidewall 201, the second sidewall 202, the fourth sidewall 204 and the honeycomb-shaped capillary structure of the first recess 20.

The plurality of second supporting columns 42 are arranged on the second bottom surface 30a of the second recess 30 in an array. A part of the plurality of second supporting columns 42 is located among the first sidewall 301, the second sidewall 302, the third sidewall 203 and the honeycomb-shaped liquid storing structure of the second recess 30. The other part of the plurality of second supporting columns 42 is located among the first sidewall 301, the second sidewall 302, the fourth sidewall 304 and the honeycomb-shaped liquid storing structure of the second recess 30. Preferably but not exclusively, the first supporting columns 41 are formed on the first casing 2 by an etching process. The plurality of first supporting columns 41 are integrally formed with the first casing 2 in one piece. Preferably but not exclusively, the second supporting columns 42 are formed on the second casing 3 by an etching process. The plurality of second supporting columns 42 are integrally formed with the second casing 3 in one piece. Since the plurality of supporting structures 4 are disposed in the vapor chamber 1, the structure of the vapor chamber 1 is strengthened and the deformation of the surfaces of the first casing 2 or the second casing 3 is avoided.

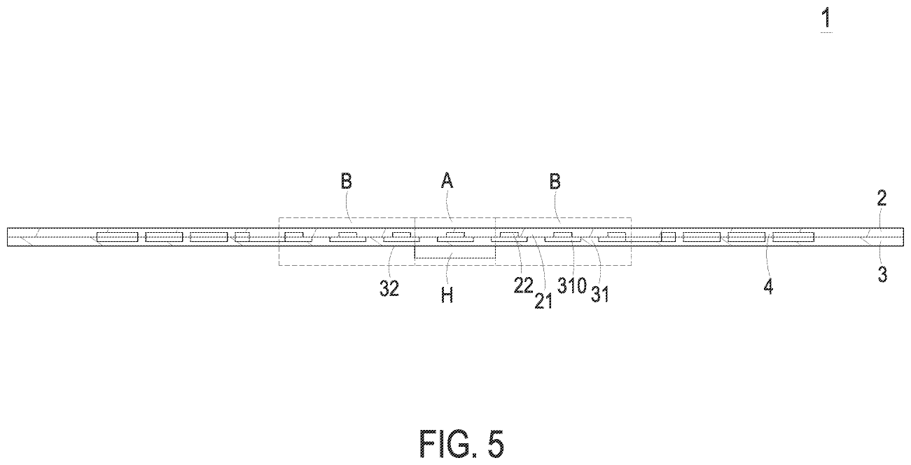

FIG. 5 is a schematic cross-sectional view illustrating the vapor chamber according to the first embodiment of the present disclosure, wherein the vapor chamber is in contact with a heat source. As shown in FIG. 5, an outer surface 32 of the second casing 3 of the vapor chamber 1 of the present disclosure is connected with or in contact with a heat source H, and at least a part of the plurality of pillars 21 and at least a part of the plurality of liquid storing concaves 310 are corresponding in position to the heat source H, so as to dissipate the thermal energy from the heat source H. Preferably but not exclusively, the heat source H is an electronic device. As shown in FIG. 5, an evaporation zone A of the vapor chamber 1 is defined at the area of the location of the pillars 21 and the liquid storing concaves 310 corresponding in position to the heat source H, and a transportation zone B is defined at the area of the location of the pillars 21 and the liquid storing concaves 310 other than the evaporation zone A. Since the heat source H is in contact with the outer surface 32 of the second casing 3, the thermal energy from the heat source H is transferred to the working liquid inside the evaporation zone A, and the working fluid in the liquid storing concaves 310 is vaporized from liquid to gas and flows into fluid channel 22 thereafter. Then, the vaporized working fluid is transferred from the evaporation zone A to the transportation zone B for cooling and condensing. In the meanwhile, the working fluid inside the transportation zone B is absorbed by the capillary force of the honeycomb-shaped capillary structure formed by the plurality of pillars 21 and the fluid channel 22, so that the working fluid diffuses in the direction away from the heat source H, and flows back to the evaporation zone A through the microstructure 31 thereafter. Since the working fluid is vaporized and condensed cyclically and transferred from a hot end to a cold end by the capillary force of the honeycomb-shaped capillary structure, the advantages of equalizing temperature rapidly and enhancing the heat dissipation efficiency are achieved. Moreover, since the plurality of liquid storing concaves 310 are disposed in the vapor chamber 1, the storage of the working liquid is increased, and the heat dissipation efficiency of the vapor chamber 1 is enhanced.

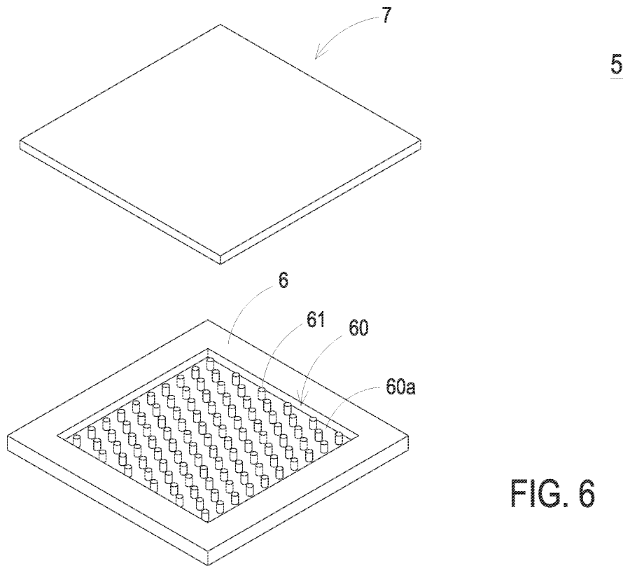

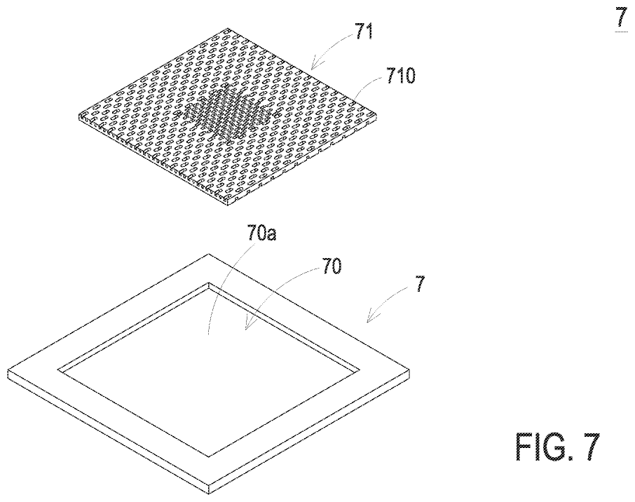

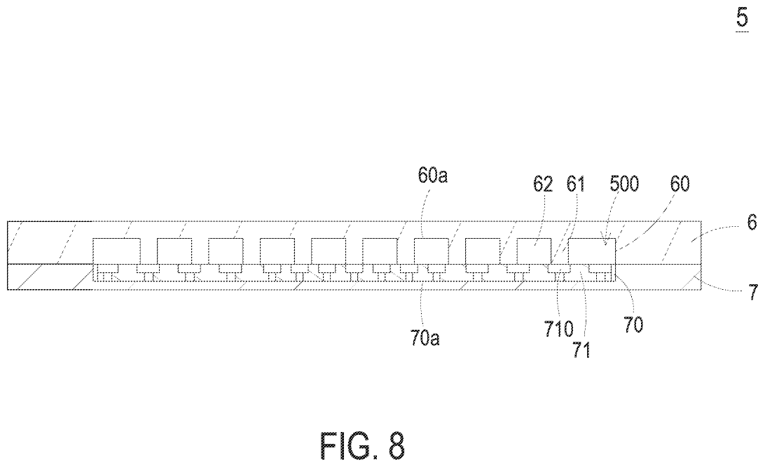

FIG. 6 is a schematic perspective view illustrating a vapor chamber according to a second embodiment of the present disclosure. FIG. 7 is a schematic exploded view illustrating the vapor chamber according to the second embodiment of the present disclosure. FIG. 8 is a schematic cross-sectional view illustrating the vapor chamber according to the second embodiment of the present disclosure. In the second embodiment of the present disclosure, the vapor chamber 5 comprises a first casing 6, a second casing 7 and a working fluid (not shown). The first casing 6 has a first recess 60 and a plurality of pillars 61. The first recess 60 has a first bottom surface 60a, and the plurality of pillars 61 are disposed on the first bottom surface 60a. A fluid channel 62 is formed among the plurality of pillars 61. The second casing 7 has a second recess 70 and a microstructure 71. The second recess 70 has a second bottom surface 70a, and the microstructure 71 is disposed on the second bottom surface 70a. The microstructure 71 has a plurality of liquid storing concaves 710. When the first casing 6 is assembled with the second casing 7, the first casing 6 and the second casing 7 are sealed to form an accommodating space 500, and the plurality of pillars 61 are corresponding in position to the microstructure 71. The working liquid is accommodated within the accommodating space 500. The working liquid is absorbed among the plurality of pillars 61 and the microstructure 71 by capillary force, and flows in the fluid channel 62 and the plurality of liquid storing concaves 710. In this embodiment, since the plurality of pillars 61 of the first casing 6 are corresponding in position to the microstructure 71 of the second casing 7, the mesh structure of the conventional vapor chamber can be replaced by the plurality of pillars 61 and the microstructure 71 and a thinner thickness of the vapor chamber 5 is achieved. Preferably but not exclusively, the thickness of the vapor chamber 5 is less than or equal to 0.6 millimeter (mm). More preferably, the thickness of the vapor chamber 5 is less than or equal to 0.3 millimeter (mm). In addition, since the vapor chamber 5 of this embodiment is unnecessary to use a metal-made mesh structure of the conventional vapor chamber, the advantages of reducing the resistance of the working fluid, transporting thermal energy rapidly and enhancing the heat dissipation efficiency are achieved.

In an embodiment, the first casing 6 and the second casing 7 are made of a metal material, respectively, for example but not limited to a copper or a copper alloy. The accommodating space 500 is a vacuum chamber. The plurality of pillars 61 are arranged on the first bottom surface 60a of the first recess 60 in an array. In other embodiment, the contour of the microstructure 71 matches with the contour of the second recess 70, so that the microstructure 71 is embedded in the second recess 70.

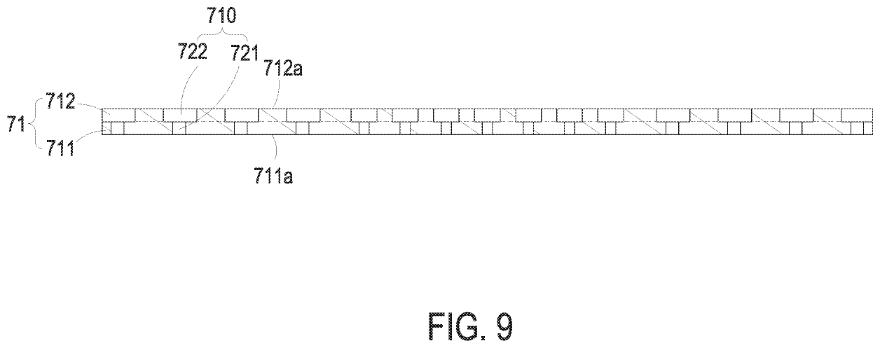

FIG. 9 is a schematic cross-sectional view illustrating a microstructure of the vapor chamber according to the second embodiment of the present disclosure. In this embodiment, the microstructure 71 is assembled with the second casing 7. The microstructure 71 is made of a metal material, and the plurality of liquid storing concaves 710 of the microstructure 71 are formed by an etching process, but not limited thereto. The microstructure 71 comprises a first layer 711 and a second layer 712, and the first layer 711 is in connection with the second layer 712. The first layer 711 has a first layer surface 711a, and the second layer 712 has a second layer surface 712a. The first layer surface 711a and the second layer surface 712a are disposed on two opposite sides of the microstructure 71. Each of the liquid storing concaves 710 has a first opening 721 and a second opening 722. The first opening 721 is disposed on and runs through the first layer 711 of the microstructure 71. The second opening 722 is disposed on and runs through the second layer 712 of the microstructure 71. The first opening 721 is at least partially in fluid communication with the second opening 722, and the liquid storing concave 710 penetrates through the first layer surface 711a and the second layer surface 712a of the microstructure 71.

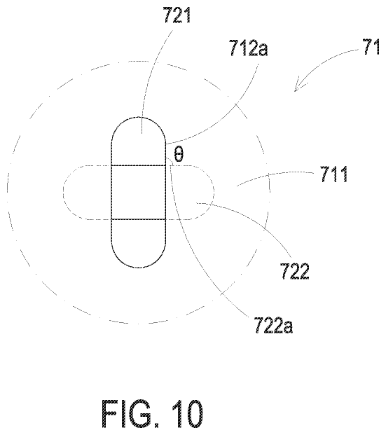

FIG. 10 is a schematic partial-perspective view illustrating the microstructure of the vapor chamber according to the second embodiment of the present disclosure. As shown in FIGS. 9 and 10, in this embodiment, preferably but not exclusively, the first opening 721 and the second opening 722 of each of the liquid storing concaves 710 are elongated holes with the same contour. The first opening 721 has a first long side 721a, the second opening 722 has a second long side 722a, and an angle θ is form between the first long side 721a and the second long side 722a. In an embodiment, the angle θ is but not limited to 90 degrees, so that the first opening 721 and the second opening 722 are in fluid communication with each other in a partial overlap manner. Since the first opening 721 and the second opening 722 are partially in fluid communication with each other, the contact area of the liquid storing concave 710 and the working liquid is increased, the capillary force for absorbing the working liquid is enhanced, the fluid resistance caused by the mesh structure of the conventional vapor chamber is avoided, and the thickness of the vapor chamber 5 is further thinned.

In an embodiment, each of the first openings 721 is partially in fluid communication with portion of the plurality of second openings 722, and each of the second openings 722 is also partially in fluid communication with portion of the plurality of first openings 721. In other words, each of the first openings 721 is in fluid communication with two or more second openings 722, and each of the second openings 722 is in fluid communication with two or more first openings 721. Due to the arrangement of the first openings 721 and the second openings 722, the storage of the working liquid is increased, the fluid resistance of the mesh structure of the conventional vapor chamber is avoided, and the transporting rate of the working fluid in the liquid storing concaves 710 is enhanced.

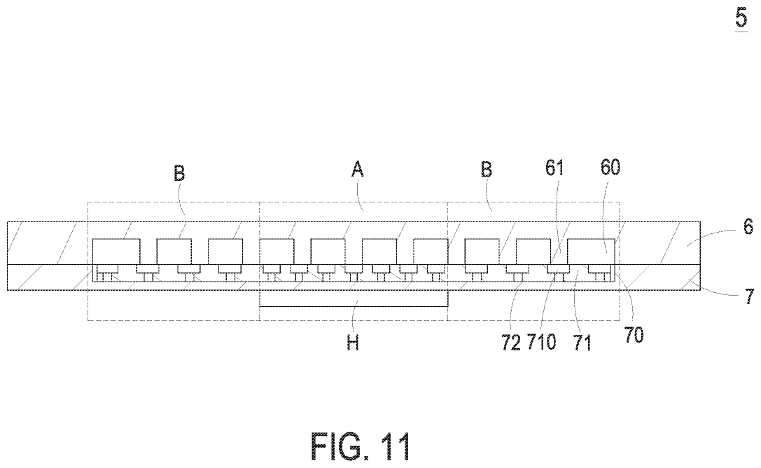

FIG. 11 is a schematic cross-sectional view illustrating the vapor chamber according to the second embodiment of the present disclosure, wherein the vapor chamber is in contact with a heat source. As shown in FIG. 11, in this embodiment, an outer surface 72 of the second casing 7 of the vapor chamber 5 is connected with or in contact with a heat source H, and at least a part of the plurality of pillars 61 and at least a part of the plurality of liquid storing concaves 710 are corresponding in position to the heat source H, so as to dissipate the thermal energy from the heat source H. As shown in FIG. 11, an evaporation zone A is defined at the area of the location of the pillars 61 and the liquid storing concaves 710 corresponding in position to the heat source H, and a transportation zone B is defined at the area the location of the pillars 61 and the liquid storing concaves 710 other than the evaporation zone A. Since the heat source H is in contact with the outer surface 72 of the second casing 7, the thermal energy from the heat source H is transferred to the working liquid inside the evaporation zone A, and the working fluid in the liquid storing concaves 710 is vaporized from liquid to gas and flows into fluid channel 62 thereafter. Then, the vaporized working fluid is transferred from the evaporation zone A to the transportation zone B and diffused in the direction away from the heat source H through the fluid channel 62 for cooling and condensing. In the meanwhile, the working fluid inside the transportation zone B is absorbed t the liquid storing concaves 710 of the microstructure 71 by the capillary force of the honeycomb-shaped capillary structure, and further flows back to the evaporation zone A. Since the working fluid is vaporized and condensed cyclically and transferred from a cold end to a hot end by the capillary force of the honeycomb-shaped capillary structure, the advantages of equalizing temperature rapidly and enhancing the heat dissipation efficiency are achieved. Moreover, since the plurality of liquid storing concaves 710 are disposed in the vapor chamber 5, the storage of the working liquid is increased, and the heat dissipation efficiency of the vapor chamber 5 is enhanced.

In an embodiment, the density of the liquid storing concaves 710 in the evaporation zone A of the vapor chamber 5 is greater than the density of the liquid storing concaves 710 in the transportation zone B, so that the capillary force to the working liquid in the evaporation zone A is greater than that in the transportation zone B. Therefore, when the vaporized working liquid in the evaporation zone A is condensed to liquid state and flows into the fluid channel 62, the working liquid in the transportation zone B can be rapidly transported back to the evaporation zone A, and the heat dissipation efficiency of the vapor chamber 5 is enhanced. The dense area of the liquid storing concaves 710 of the microstructure 71 can be adjusted according to the position of the heat source H, and can be changed according to the practical requirements.

In summary, the present disclosure provides a vapor chamber. The arrangement of the pillars and the microstructure of the vapor chamber of the present disclosure replace the mesh structure of the conventional vapor chamber, so as to achieve the advantages of slimness, reducing the resistance of the working fluid, equalizing temperature rapidly and enhancing the heat dissipation efficiency. In addition, the liquid storing concaves of the vapor chamber of the present disclosure increase the storage of the working liquid, and the heat dissipation efficiency of the vapor chamber is enhanced. Moreover, the supporting structures of the vapor chamber of the present disclosure enhance the structural strength of the vapor chamber and avoid the deformation of the surfaces of the first casing and the second casing. Furthermore, since the density of the liquid storing concaves in the evaporation zone of the vapor chamber is greater than that in the transportation zone, the working liquid is easier to be absorbed and transported to the evaporation zone by the capillary force, and the heat dissipation efficiency of the vapor chamber is enhanced.

While the disclosure has been described in terms of what is presently considered to be the most practical and preferred embodiments, it is to be understood that the disclosure needs not be limited to the disclosed embodiment.

What is claimed is:

1. A vapor chamber, comprising:
a first casing having a first recess and a plurality of pillars, wherein the first recess has a first bottom surface, the plurality of pillars are disposed on the first bottom surface, and a fluid channel is formed among the plurality of pillars;
a second casing having a second recess and a microstructure, wherein the second recess has a second bottom surface, the microstructure is disposed on the second bottom surface, and the microstructure has a plurality of liquid storing concaves, wherein the first casing is assembled with the second casing, the first recess and the second recess are sealed to form an accommodating space, and the plurality of pillars are corresponding in position to the microstructure; and
a working fluid accommodated in the accommodating space, absorbed among the plurality of pillars and the microstructure by the capillary force, and flowing in the fluid channel and the plurality of liquid storing concaves.

2. The vapor chamber according to claim 1, wherein each of the plurality of pillars is a polygonal cylinder, and each of the plurality of liquid storing concaves is a polygonal concave.

3. The vapor chamber according to claim 2, wherein the plurality of pillars are hexagon cylinders and arranged in an interleaved array to form a honeycomb-shaped capillary structure, wherein the plurality of liquid storing concaves are hexagon concaves and arranged in an interleaved array to form a honeycomb-shaped liquid storing structure.

4. The vapor chamber according to claim 1, wherein the plurality of pillars are misaligned with the plurality of liquid storing concaves, respectively, and the fluid channel is in fluid communication with the plurality of liquid storing concaves.

5. The vapor chamber according to claim 4, wherein a free end of each of the pillars is partially covered on an opening of a corresponding one of the plurality of the liquid storing concaves.

6. The vapor chamber according to claim 1, wherein the plurality of pillars are aligned with the plurality of liquid storing concaves, respectively, and the fluid channel is in fluid communication with the plurality of liquid storing concaves.

7. The vapor chamber according to claim 5, wherein the area of an opening of each of the liquid storing concaves is greater than a surface area of a free end of a corresponding one of the plurality of pillars.

8. The vapor chamber according to claim 1, further comprising a plurality of supporting structures, wherein the plurality of supporting structures are disposed between the first bottom surface of the first casing and the second bottom surface of the second casing.

9. The vapor chamber according to claim 8, wherein each of the supporting structures has a first supporting column and a second supporting column, the first supporting column is disposed on the first bottom surface, and the second supporting column is disposed on the second bottom surface, wherein when the first casing and the second casing are assembled, the first supporting column and the second supporting column are aligned and in contact with each other.

10. The vapor chamber according to claim 1, wherein the plurality of pillars of the first casing and the plurality of liquid storing concaves of the second casing are formed by an etching process, respectively, and any two of the plurality of liquid storing concaves are not in fluid communication with each other.

11. The vapor chamber according to claim 1, wherein the second casing is connected with or in contact with a heat source, and the heat source is corresponding in position to a part of the plurality of pillars and a part of the plurality of liquid storing concaves, wherein an evaporation zone is defined at the area of the location of the plurality of pillars and the plurality of liquid storing concaves corresponding in position to the heat source, and a transportation zone is defined at the area of the location of the plurality of pillars and the plurality of liquid storing concaves other than the evaporation zone, wherein the density of the liquid storing concaves in the evaporation zone is greater than the density of the liquid storing concaves in the transportation zone.

12. The vapor chamber according to claim 1, wherein the plurality of liquid storing concaves of the microstructure are formed by an etching process.

13. The vapor chamber according to claim 1, wherein the thickness of the vapor chamber is less than or equal to 0.6 millimeter.

14. The vapor chamber according to claim 1, wherein the first casing and the second casing are made of a metal material, respectively, and the accommodating space of the vapor chamber is a vacuum chamber.
